(19) United States
(12) Patent Application Publication
(10) Pub. No.: US 2005/0221000 A1
(43) Pub. Date: Oct. 6, 2005

(54) Method of forming a metal layer

(75) Inventors: Taro Ikeda, Nirasaki-City (JP); Tsukasa Matsuda, Kitakoma-gun (JP); Fenton R. McFeely, Ossining, NY (US); Sandra G. Malhotra, Beacon, NY (US); Andrew H. Simon, Fishkill, NY (US); John J. Yurkas, Stamford, CT (US)

Correspondence Address: PILLSBURY WINTHROP SHAW PITTMAN, LLP, P.O. BOX 10500, MCLEAN, VA, 22102, US

(73) Assignees: Tokyo Electron Limited, Tokyo (JP); International Business Machines Corporation, Armonk, NY (US)

(21) Appl. No.: 10/813,680

(22) Filed: Mar. 31, 2004

(51) Int. Cl. B05D 3/00; H05H 1/24; C23C 16/00

(52) U.S. Cl. 427/248.1; 427/532; 118/723 R; 118/719

(57) ABSTRACT

A method and a processing tool are provided for forming a metal layer with improved morphology on a substrate. The method includes pre-treating the substrate by exposing the substrate to excited species in a plasma, exposing the pre-treated substrate to a process gas containing a metal-carbonyl precursor, and forming a metal layer on the pre-treated substrate surface by a chemical vapor deposition process. The metal-carbonyl precursor can contain W(CO)₆, Ni(CO)₄, Mo(CO)₆, CO₂(CO)₈, Rh₄(CO)₁₂, Re₂(CO)₁₀, Cr(CO)₆, or Ru₃(CO)₁₂ or any combination thereof, and the metal layer can contain W, Ni, Mo, Co, Rh, Re, Cr, or Ru, or any combination thereof, respectively.

### FIELD OF THE INVENTION

The present invention relates to semiconductor processing, and more particularly, to a method of forming a metal layer.

### BACKGROUND OF THE INVENTION

The introduction of copper (Cu) metal into multilayer metallization schemes for manufacturing integrated circuits, can require the use diffusion barriers/liners to promote adhesion and growth of the Cu layers, and to chemically isolate the Cu from the dielectric material to prevent diffusion of Cu into the dielectric material.

Barriers/liners that are deposited onto dielectric materials can include refractive materials such as tungsten (W), molybdenum (Mo), and tantalum (Ta), that are non-reactive and immiscible with Cu and can offer low electrical resistivity. Basic material properties of W, such as electrical resistivity, thermal stability, and diffusion barrier properties make W layers suitable for use in advanced Cu-based interconnect applications. Current integration schemes that integrate Cu metallization and dielectric materials can require W barrier/liner deposition processes at substrate temperatures between about 400° C. and about 500° C., or lower.

W layers can be formed on a substrate in a thermal chemical vapor deposition (TCVD) process by thermally decomposing a tungsten-halide precursor, e.g., tungsten hexafluoride (WF₆), in the presence of a reducing gas such as hydrogen or silane. A drawback to using tungsten-halide precursors is incorporation of halide by-products in the W layer that can degrade the material properties of the W layer. A non-halogen containing tungsten precursor, such as a tungsten-carbonyl precursor, can be used to alleviate the abovementioned drawbacks associated with tungsten-halide precursors. However, material properties of W layers that are formed by thermal decomposition of tungsten-carbonyl precursors (e.g., W(CO)₆), can deteriorate due to incorporation of CO reaction by-products into the thermally deposited W layers, resulting in increase in the electrical resistivity of the W layers and formation of W layers with poor conformality.

### SUMMARY OF THE INVENTION

A method is provided for forming a metal layer on a substrate by providing a substrate in a process chamber, pre-treating the substrate by exposing it to excited species in a plasma, exposing the pre-treated substrate to a process gas containing a metal-carbonyl precursor, and forming a metal layer on the pre-treated substrate by a chemical vapor deposition process.

In one embodiment of the invention, the metal-carbonyl precursor can contain W(CO)₆, Ni(CO)₄, Mo(CO)₆, CO₂(CO)₈, Rh₄(CO)₁₂, Re₂(CO)₁₀, Cr(CO)₆, or Ru₃(CO)₁₂, or a combination thereof, and the metal layer can contain W, Ni, Mo, Co, Rh, Re, Cr, or Ru, or a combination of two or more thereof, respectively.

In one embodiment of the invention, a method is provided for forming a tungsten layer on a substrate by providing a substrate in a process chamber, pre-treating the substrate by exposing it to excited species in a plasma, wherein the plasma is formed from a pre-treatment gas containing H₂, N₂, NH₃, He, Ne, Ar, Kr, or Xe, or a combination of two or more thereof, exposing the pre-treated substrate to a process gas containing a W(CO)₆ precursor, and forming a tungsten layer on the pre-treated substrate by a thermal chemical vapor deposition process.

A processing tool is provided for forming a metal layer. The processing tool includes a transfer system configured for transferring a substrate within the processing tool, at least one processing system configured for pre-treating a substrate by exposing the substrate to excited species in a plasma and exposing the pre-treated substrate to a process gas containing a metal-carbonyl precursor to form a metal layer on the pre-treated substrate in chemical vapor deposition process, and a controller configured to control the processing tool.

### BRIEF DESCRIPTION OF THE DRAWINGS

In the drawings:

FIGS. 1-5B are schematic diagrams of processing systems for processing a substrate according to embodiments of the invention;

FIG. 6 is a schematic diagram of a processing system for forming a metal layer on a substrate according to an embodiment of the invention;

FIG. 7 shows a simplified block diagram of a processing tool according to an embodiment of the invention;

FIG. 8 is a flowchart for processing a substrate according to an embodiment of the invention;

FIG. 9A shows a cross-sectional scanning electron microscope (SEM) picture of a W layer formed on a substrate containing a microstructure;

FIG. 9B shows a cross-sectional SEM picture of a W layer formed on a pre-treated substrate containing a microstructure according to an embodiment of the invention;

FIG. 10A shows a cross-sectional SEM picture of a W layer formed on a substrate containing a microstructure; and

FIG. 10B shows a cross-sectional SEM picture of a W layer formed on a pre-treated substrate containing a microstructure according to an embodiment of the invention.

### DETAILED DESCRIPTION OF THE INVENTION

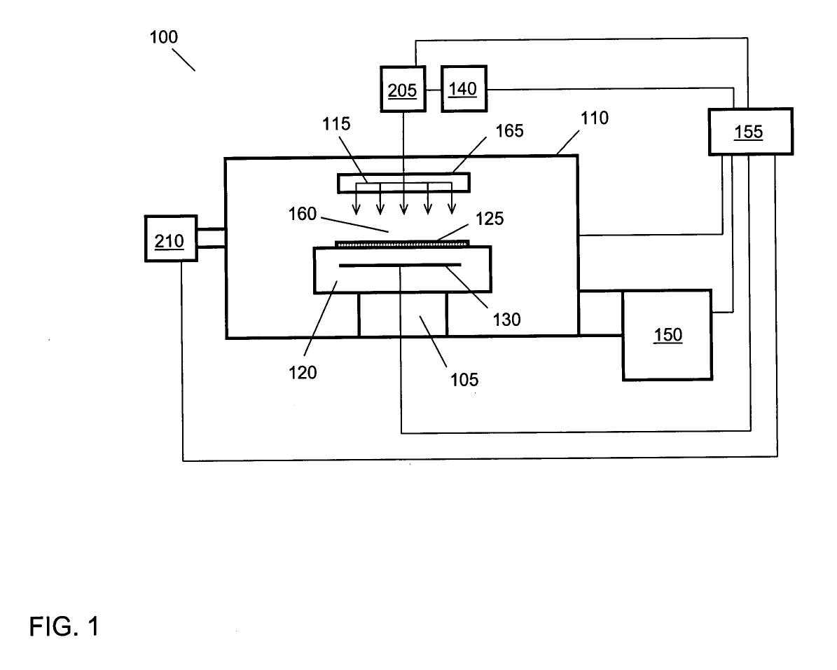

FIG. 1 shows a processing system 100 for processing a substrate according to an embodiment of the invention. The processing system 100 includes a process chamber 110 having a pedestal 105 for mounting a substrate holder 120 for supporting and heating/cooling a substrate 125, a gas injection system 140 for introducing a gas 115 to the process chamber 110, and a vacuum pumping system 150. The gas 115 can contain a pre-treatment gas that includes H₂, N₂, NH₃, He, Ne, Ar, Kr, or Xe or a combination of two or more thereof, that forms excited species (e.g., radicals and ions) in a plasma for pre-treating the substrate 125, or a process gas containing a metal-carbonyl precursor for forming a metal layer on the pre-treated substrate 125 in a chemical vapor deposition process. The gas injection system 140 allows independent control over the delivery of the gas 115 to the process chamber 110 from ex-situ gas sources (not shown). The gas 115 can be introduced into the process chamber 110 via the gas injection system 140 and the process pressure is adjusted. For example, controller 155 is used to control the vacuum pumping system 150 and gas injection system 140.

Substrate 125 is transferred in and out of chamber 110 through a slot valve (not shown) and chamber feed-through (not shown) via a robotic substrate transfer system 210 where it is received by substrate lift pins (not shown) housed within substrate holder 120 and mechanically translated by devices housed therein. Once the substrate 125 is received from the substrate transfer system, it is lowered to an upper surface of the substrate holder 120.

The substrate 125 can be affixed to the substrate holder 120 via an electrostatic clamp (not shown). Furthermore, the substrate holder 120 includes a heater element 130 and the substrate holder 120 can further include a cooling system including a re-circulating coolant flow that receives heat from the substrate holder 120 and transfers heat to a heat exchanger system (not shown). Moreover, gas may be delivered to the backside of the substrate to improve the gas-gap thermal conductance between the substrate 125 and the substrate holder 120. Such a system can be utilized when temperature control of the substrate is required at elevated or reduced temperatures.

With continuing reference to FIG. 1, gas 115 is introduced to the processing region 160 from the gas injection system 140. The gas 115 can be introduced to the processing region 160 through a gas injection plenum (not shown), a series of baffle plates (not shown) and a multi-orifice showerhead gas injection plate 165. In one embodiment of the invention, the gas injection system 140 can be configured to facilitate rapid cycling of gases for an atomic layer chemical vapor deposition (ALCVD) process. The processing system 100 contains a remote plasma generator 205 that can be utilized for forming excited species for pre-treating the substrate 125 and for dry cleaning the process chamber 110. Vacuum pump system 150 can include a turbo-molecular vacuum pump (TMP) capable of a pumping speed up to about 5,000 liters per second (and greater), and a gate valve for throttling the chamber pressure. TMPs are useful for low pressure processing, typically less than about 50 mTorr. For high pressure processing (i.e., greater than about 100 mTorr), a mechanical booster pump and dry roughing pump can be used.

A controller 155 includes a microprocessor, a memory, and a digital I/O port capable of generating control voltages sufficient to communicate and activate inputs to the processing system 100 as well as monitor outputs from the processing system 100. Moreover, the controller 155 is coupled to and exchanges information with the process chamber 110, the gas injection system 140, the remote plasma generator 205, the heating element 130, the substrate transfer system 210, and the vacuum pump system 150. For example, a program stored in the memory can be utilized to control the aforementioned components of a processing system 100 according to a stored process recipe. One example of controller 155 is a DELL PRECISION WORKSTATION 610™, available from Dell Corporation, Austin, Tex.

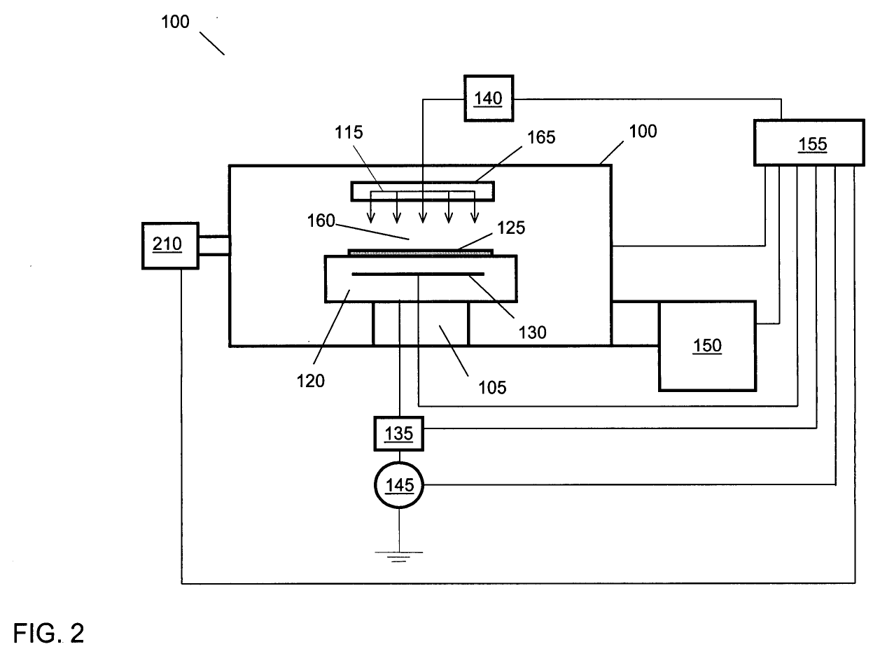

FIG. 2 shows a processing system for processing a substrate according to an embodiment of the invention. The processing system 100 of FIG. 2 is capable of forming and sustaining a plasma in the process chamber 110. In the embodiment shown in FIG. 2, the substrate holder 120 can further serve as an electrode through which radio frequency (RF) power is coupled to plasma in the processing region 160. For example, a metal electrode (not shown) in the substrate holder 120 can be electrically biased at a RF voltage via the transmission of RF power from an RF generator 145 through an impedance match network 135 to the substrate holder 120. The RF bias serves to heat electrons and, thereby, form and maintain a plasma. A typical frequency for the RF bias can range from about 0.1 MHz to about 100 MHz and can be about 13.6 MHz.

In an alternate embodiment, RF power can be applied to the substrate holder 120 at multiple frequencies. Furthermore, the impedance match network 135 serves to maximize the transfer of RF power to plasma in processing chamber 110 by minimizing the reflected power. Match network topologies (e.g., L-type, π-type, T-type) and automatic control methods are known in the art. In FIG. 2, the controller 155 is coupled to and exchanges information with the process chamber 110, the RF generator 145, the impedance match network 135, the gas injection system 140, the substrate transfer system 210, and the vacuum pump system 150.

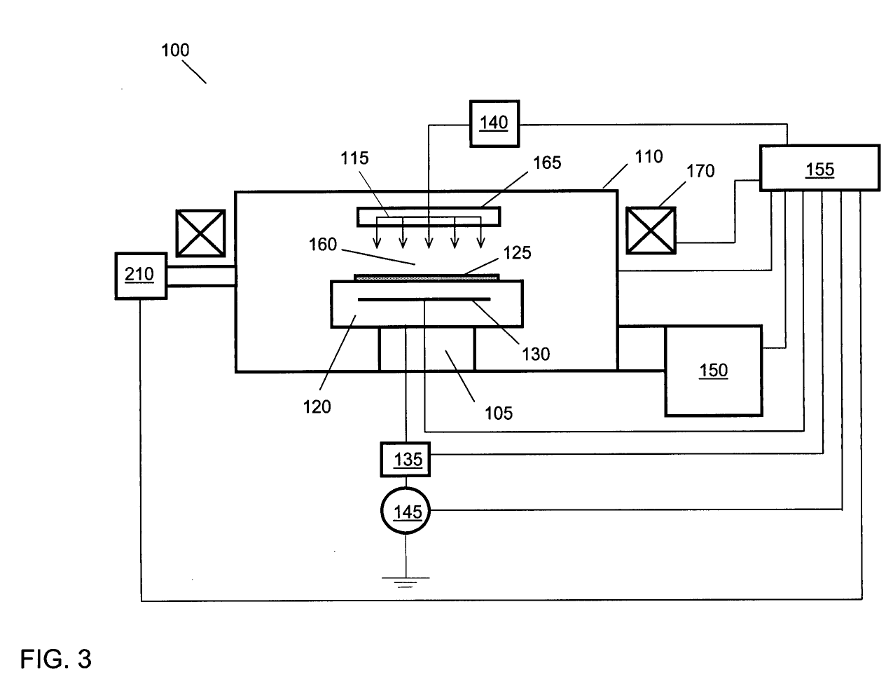

FIG. 3 shows a processing system for processing a substrate according to an embodiment of the invention. The processing system 100 of FIG. 3 further includes either a mechanically or electrically rotating DC magnetic field system 170, in order to potentially increase plasma density and/or improve plasma processing uniformity, in addition to those components described with reference to FIG. 2. Moreover, the controller 155 is coupled to the rotating magnetic field system 170 in order to regulate the speed of rotation and field strength.

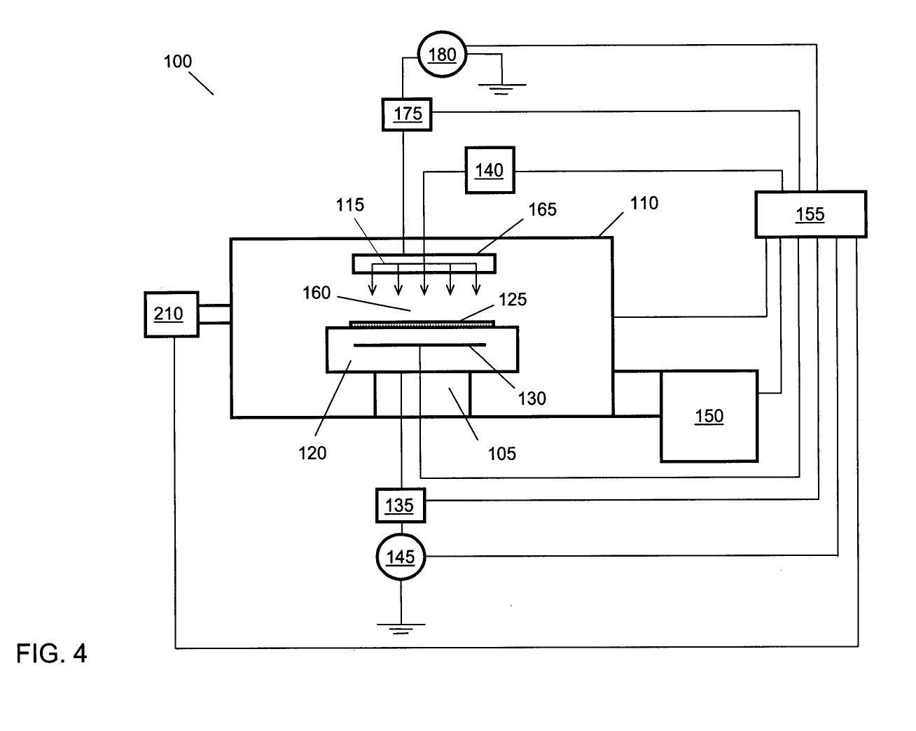

FIG. 4 shows a processing system for processing a substrate according to an embodiment of the invention. The processing system 100 of FIG. 4 includes an multi-orifice showerhead gas injection plate 165 that can also serve as an upper plate electrode to which RF power is coupled from an RF generator 180 through an impedance match network 175. A frequency for the application of RF power to the upper electrode can range from about 10 MHz to about 200 MHz and can be about 60 MHz. Additionally, a frequency for the application of power to the lower electrode can range from about 0.1 MHz to about 30 MHz and can be about 2 MHz. Moreover, the controller 155 is coupled to the RF generator 180 and the impedance match network 175 in order to control the application of RF power to the upper electrode 165.

In one embodiment of the invention, the substrate holder 120 in FIG. 4 can be electrically grounded. In an alternate embodiment, a DC bias can be applied to the substrate holder 120. In still another embodiment, the substrate holder 120 can be electrically isolated from the processing system 100. In this setup, a floating potential can be formed on the substrate holder 120 and on the substrate 125 when the plasma is on.

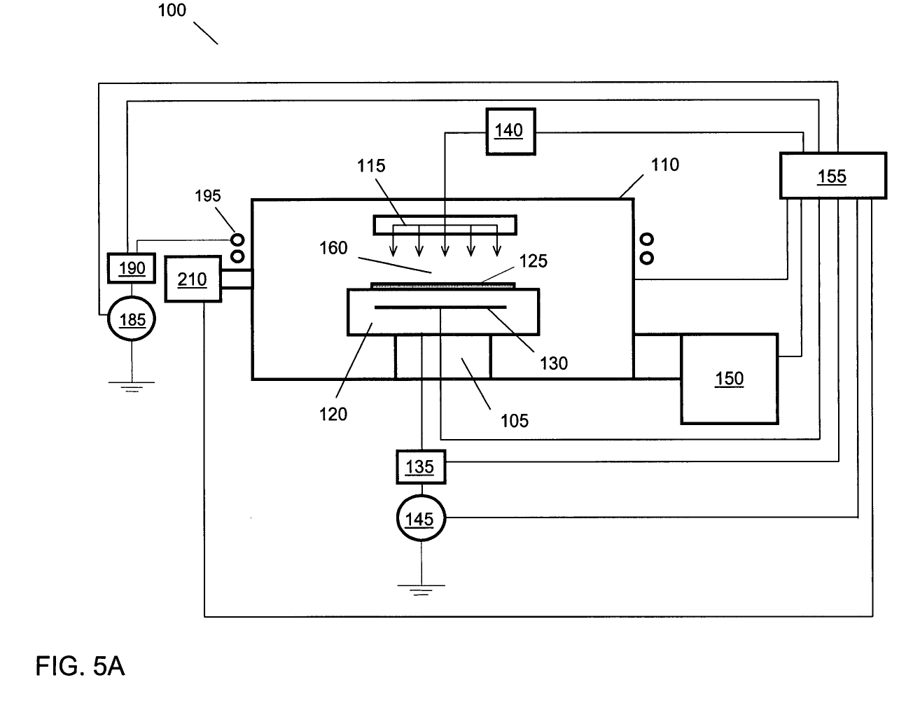

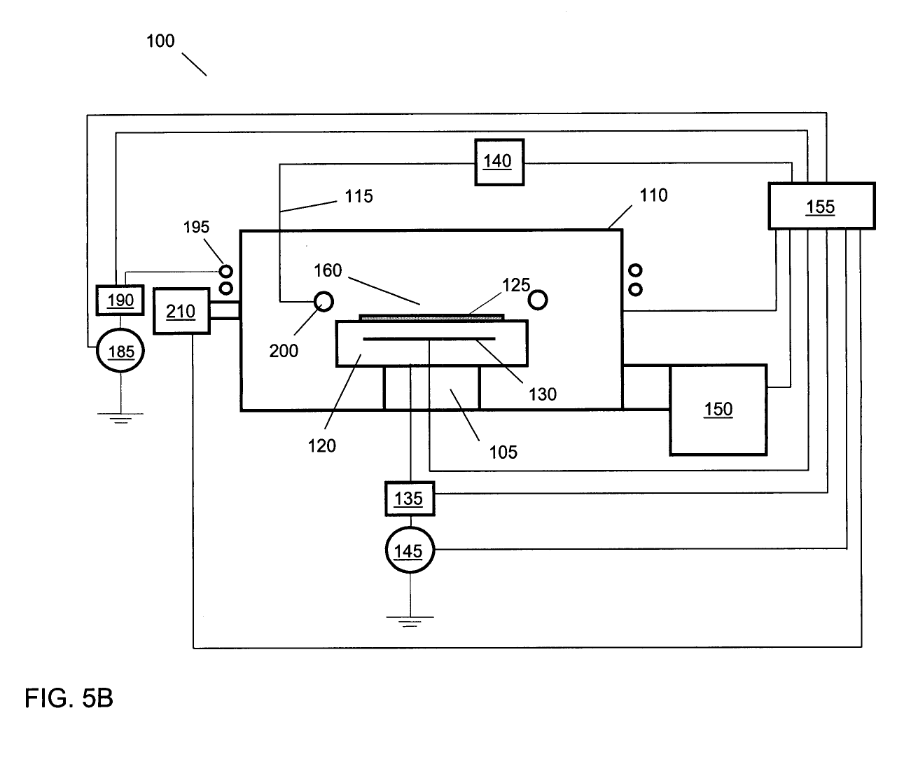

FIG. 5A shows a processing system for processing a substrate according to an embodiment of the present invention. The processing system of FIG. 2 is modified to further include an inductive coil 195 to which RF power is coupled via a RF generator 185 through an impedance match network 190. RF power is inductively coupled from the inductive coil 195 through a dielectric window (not shown) to the processing region 160. A frequency for the application of RF power to the inductive coil 180 can range from about 0.1 MHz to about 100 MHz and can be about 13.6 MHz. Similarly, a frequency for the application of power to the substrate holder 120 can range from about 0.1 MHz to about 100 MHz and can be about 13.6 MHz. In addition, a slotted Faraday shield (not shown) can be employed to reduce capacitive coupling between the inductive coil 195 and plasma. Moreover, the controller 155 is coupled to the RF generator 185 and the impedance match network 190 in order to control the application of power to the inductive coil 195.

FIG. 5B shows a processing system for processing a substrate according to an embodiment of the present invention. The processing system of FIG. 5A is modified to include a gas injection ring 200 configured for introducing gas 115 to the processing region 160.

In one embodiment of the invention, the substrate holder 120 in FIGS. 5A and 5B can be electrically grounded. In an alternate embodiment, a DC bias can be applied to the substrate holder 120. In still another embodiment, the substrate holder 120 can be electrically isolated from the processing system 100. In this setup, a floating potential can be formed on the substrate holder 120 and on the substrate 125 when the plasma is on.

In another embodiment of the invention, an antenna (not shown) can be used to form a plasma through a dielectric window to the processing region 160. In yet another embodiment, the plasma can be formed using electron cyclotron resonance (ECR). In still another embodiment, the plasma can be formed from the launching of a Helicon wave. In another embodiment, the plasma can formed from a propagating surface wave.

It is to be understood that the processing systems in FIGS. 1-5B are shown for exemplary purposes only, as many variations of the specific hardware and software can be used to implement processing systems in which the present invention may be practiced, and these variations will be readily apparent to one having ordinary skill in the art.

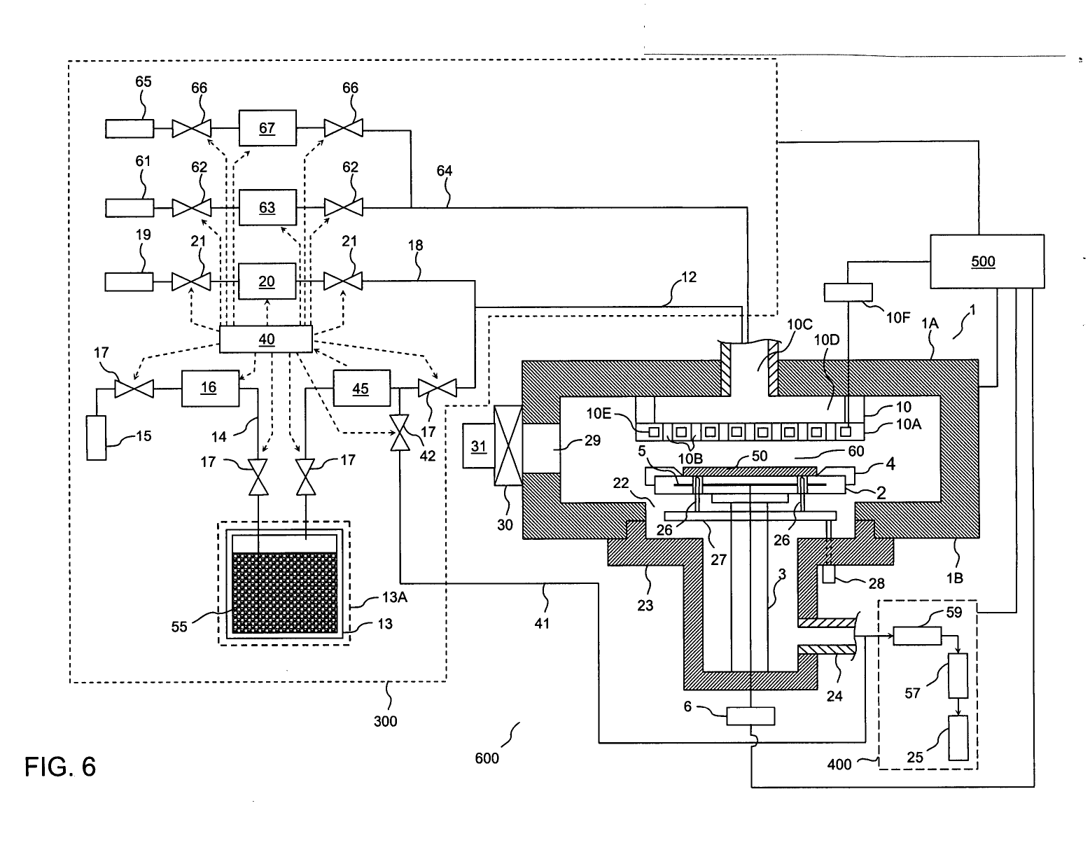

FIG. 6 is a schematic diagram of a processing system for forming a metal layer on a substrate according to an embodiment of the invention. The processing system 600 contains a process chamber 1 that contains an upper chamber section 1A, a lower chamber section 1B, and an exhaust chamber 23. A circular opening 22 is formed in the middle of lower chamber section 1B, where bottom section 1B connects to exhaust chamber 23.

Provided inside process chamber 1 is a substrate holder 2 for horizontally holding a substrate (wafer) 50 to be processed. The substrate holder 2 is supported by a cylindrical support member 3, which extends upward from the center of the lower part of exhaust chamber 23. A guide ring 4 for positioning the substrate 50 on the substrate holder 2 is provided on the edge of substrate holder 2. Furthermore, the substrate holder 2 contains a heater 5 that is controlled by power source 6, and is used for heating the substrate 50. The heater 5 can be a resistive heater. Alternately, the heater 5 may be a lamp heater.

During processing, the heated substrate 50 can, for example, thermally decompose a W(CO)₆ precursor and enable formation of a W layer on the substrate 50 in a chemical vapor deposition (CVD) process. The CVD process can, for example, be a thermal chemical vapor deposition (TCVD) process, an atomic layer chemical vapor deposition (ALCVD) process, or a plasma-enhanced chemical vapor deposition (PECVD) process. The substrate holder 2 is heated to a pre-determined temperature that is suitable for forming the desired W layer onto the substrate 50. A heater (not shown) is embedded in the walls of process chamber 1 to heat the chamber walls to a pre-determined temperature. The heater can maintain the temperature of the walls of process chamber 1 from about 40° C. to about 80° C.

A showerhead 10 is located in the upper chamber section 1A of process chamber 1. Showerhead plate 10A at the bottom of showerhead 10 contains multiple gas delivery holes 10B for delivering a process gas comprising the W(CO)₆ precursor gas into a processing zone 60 located above the substrate 50.

An opening 10C is provided in the upper chamber section 1B for introducing a process gas from gas line 12 into a gas distribution compartment 10D. Concentric coolant flow channels 10E are provided for controlling the temperature of the showerhead 10 and thereby preventing the decomposition of the W(CO)₆ precursor inside the showerhead 10. A coolant fluid such as water, can be supplied to the coolant flow channels 10E from a coolant fluid source 10F for controlling the temperature of showerhead 10 from about 20° C. to about 100° C.

The gas line 12 connects the gas delivery system 300 to process chamber 1. A precursor container 13 contains a solid W(CO)₆ precursor 55, and a precursor heater 13A is provided for heating the precursor container 13 to maintain the W(CO)₆ precursor 55 at a temperature that produces a desired vapor pressure of the W(CO)₆ precursor. The W(CO)₆ precursor 55 can have a relatively high vapor pressure, Pᵥₐₚ˜1 Torr at 65° C. Therefore, only moderate heating of the precursor source 13 and the precursor gas delivery lines (e.g., gas line 12) is required for delivering the W(CO)₆ precursor gas to the process chamber 1. Furthermore, the W(CO)₆ precursor does not thermally decompose at temperatures below about 200° C. This can significantly reduce decomposition of the W(CO)₆ precursor due to interactions with heated chamber walls and gas phase reactions.

In one embodiment, W(CO)₆ precursor vapor can be delivered to the process chamber 1 without the use of a carrier gas or, alternatively, a carrier gas can be used to enhance the delivery of the precursor to the process chamber 1. Gas line 14 can provide a carrier gas from gas source 15 to the precursor container 13, and a mass flow controller (MFC) 16 can be used to control the carrier gas flow. When a carrier gas is used, it may be introduced into the lower part of precursor container 13 so as to percolated through the solid W(CO)₆ precursor 55. Alternatively, the carrier gas may be introduced into the precursor source 13 and distributed across the top of the solid W(CO)₆ precursor 55. A sensor 45 is provided for measuring the total gas flow from the precursor container 13. The sensor 45 can, for example, comprise a MFC, and the amount of W(CO)₆ precursor delivered to the process chamber 1, can be determined using sensor 45 and mass flow controller 16. Alternatively, the sensor 45 can comprise a light absorption sensor to measure the concentration of the W(CO)₆ precursor in the gas flow to the process chamber 1.

A bypass line 41 is located downstream from sensor 45 and connects gas line 12 to exhaust line 24. Bypass line 41 provided for evacuating gas line 12 and for stabilizing the supply of the W(CO)₆ precursor to the process chamber 1. In addition, a valve 42, located downstream from the branching of gas line 12, is provided on bypass line 41.

Heaters (not shown) are provided to independently heat gas lines 12, 14, and 41, where the temperatures of the gas lines can be controlled to avoid condensation of the W(CO)₆ precursor in the gas lines. The temperature of the gas lines can be controlled from about 20° C. to about 100° C., or from about 25° C. to about 60° C.

Dilution gases can be supplied from gas source 19 to gas line 12 using gas line 18. The dilution gases can be used to dilute the process gas or to adjust the process gas partial pressure(s). Gas line 18 contains a MFC 20 and valves 21. MFCs 16 and 20, and valves 17, 21, and 42 are controlled by controller 40, which controls the supply, shutoff, and the flow of a carrier gas, the W(CO)₆ precursor gas, and a dilution gas. Sensor 45 is also connected to controller 40 and, based on output of the sensor 45, controller 40 can control the carrier gas flow through mass flow controller 16 to obtain the desired W(CO)₆ precursor flow to the process chamber 1. A reducing gas can be supplied from gas source 61 to the process chamber 1 using gas line 64, MFC 63, and valves 62. A purge gas can be supplied from gas source 65 to process chamber 1 using gas line 64, MFC 67, and valves 66. Controller 40 can control the supply, shutoff, and the flow of the reducing gas and the purge gas.

Exhaust line 24 connects exhaust chamber 23 to vacuum pumping system 400. Vacuum pump 25 is used to evacuate process chamber 1 to the desired degree of vacuum and to remove gaseous species from the process chamber 1 during processing. An automatic pressure controller (APC) 59 and a trap 57 can be used in series with the vacuum pump 25. The vacuum pump 25 can include a turbo-molecular pump (TMP) capable of a pumping seed up to about 5000 liters per second (and greater). Alternatively, the vacuum pumping system 400 can include a dry pump. During processing, the process gas can be introduced into the process chamber 1 and the chamber pressure adjusted by the APC 59. The APC 59 can comprise a butterfly-type valve or a gate valve. The trap 57 can collect unreacted precursor material and by products from the process chamber 1.

In the process chamber 1, three substrate lift pins 26 (only two are shown) are provided for holding, raising, and lowering the substrate 50. The substrate lift pins 26 are affixed to plate 27, and can be lowered to below to the upper surface of substrate holder 2. A drive mechanism 28 utilizing, for example, an air cylinder, provides means for raising and lowering the plate 27. A substrate 50 can be transferred in and out of process chamber 1 through gate valve 30 and chamber feed-through passage 29 via a robotic transfer system 31 and received by the substrate lift pins. Once the substrate 50 is received from the transfer system, it can be lowered to the upper surface of the substrate holder 2 by lowering the substrate lift pins 26.

A processing system controller 500 includes a microprocessor, a memory, and a digital I/O port capable of generating control voltages sufficient to communicate and activate inputs of the processing system 100 as well as monitor outputs from the processing system 100. Moreover, the processing system controller 500 is coupled to and exchanges information with the process chamber 1, the gas delivery system 300 that includes the controller 40 and the precursor heater 13A, the vacuum pumping system 400, the power source 6, and the coolant fluid source 10F. In the vacuum pumping system 400, the processing system controller 500 is coupled to and exchanges information with the automatic pressure controller 59 for controlling the pressure in the process chamber 1. A program stored in the memory is utilized to control the aforementioned components of a processing system 100 according to a stored process recipe. One example of processing system controller 500 is a DELL PRECISION WORKSTATION 610™, available from Dell Corporation, Austin, Tex.

In addition to semiconductor substrates, e.g., Si wafers, the substrates can, for example, comprise LCD substrates, glass substrates, or compound semiconductor substrates. The process chamber 1 can, for example, process substrates of any size, such as 200 mm substrates, 300 mm substrates, or even larger substrates.

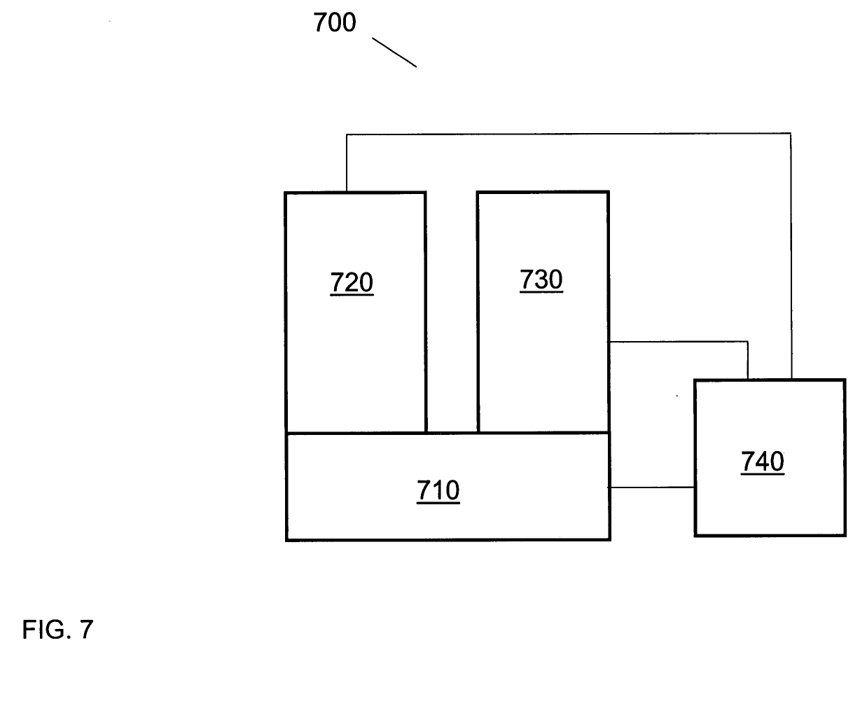

FIG. 7 shows a simplified block diagram of a processing tool according to an embodiment of the invention. The processing tool 700 includes processing systems 720 and 730, a (robotic) transfer system 710 configured for transferring substrates within the processing tool 700, and a controller 740 configured to control the processing tool 700. In another embodiment of the invention, the processing tool 700 can include a single processing system or, alternately, can include more than two processing systems. In FIG. 7, the processing systems 720 and 730 can, for example, perform either or both of the following processes: (a) pre-treat a substrate by exposing the substrate to excited species in a plasma, or (b) expose a pre-treated substrate to a metal-containing precursor to form a metal film on the pre-treated substrate in a chemical vapor deposition process. In one embodiment of the invention, the processes (a) and (b) can be carried out in the same processing system. In another embodiment of the invention, (a) and (b) can be performed in different processing systems. As with the controllers of FIGS. 1-6, the controller 240 in FIG. 7 may be implemented as a DELL PRECISION WORKSTATION 610™.

In general, various metal layers can be deposited from the corresponding metal-carbonyl precursors in a chemical vapor deposition process. This includes deposition of W, Ni, Mo, Co, Rh, Re, Cr, or Ru or any combinations of two or more thereof, metal layers from W(CO)₆, Ni(CO)₄, Mo(CO)₆, CO₂(CO)₈, Rh₄(CO)₁₂, Re₂(CO)₁₀, Cr(CO)₆, or Ru₃(CO)₁₂ precursors or any combinations thereof, respectively. A metal layer can be thermally deposited from a metal-carbonyl precursor without the use of a reducing gas. Alternately, a reducing agent, e.g. a H₂ gas, can be employed to aid in the deposition of the metal layer.

Thermal decomposition of a metal-carbonyl precursor and the formation of a metal layer, is thought to proceed predominantly by CO elimination and desorption of CO by-products from the substrate. Incorporation of CO by-products into the metal layer can result from incomplete decomposition of the metal-carbonyl precursor, incomplete removal of adsorbed CO by-products from the metal layer, and re-adsorption of CO by-products in the process chamber onto the metal layer. Incorporation of CO reaction by-products into the metal layer can increase the electrical resistivity of the metal layer and lead to poor surface morphology due to abnormal growth of nodules (metal particles) on the surface of the metal layer and/or in the metal layer. In one embodiment of the current invention, a substrate is pre-treated with excited species in a plasma and a metal layer is formed on the pre-treated substrate by a chemical vapor deposition process using a process gas containing a metal-carbonyl precursor. The pre-treatment of the substrate results in improved morphology of the deposited metal layer.

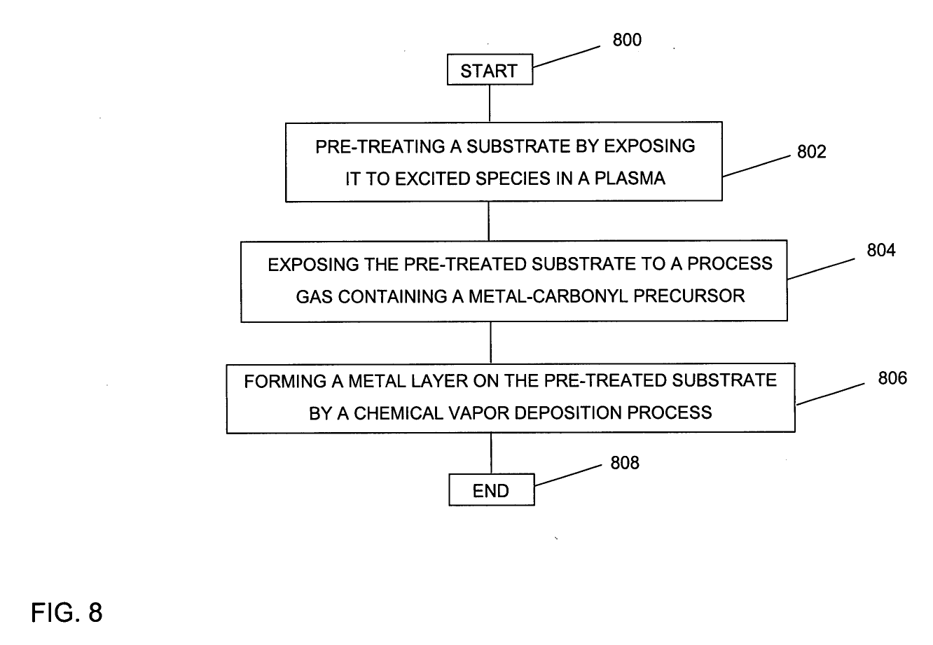

FIG. 8 is a flowchart for processing a substrate according to an embodiment of the invention. At 800, the process is started. At 802, a surface is pre-treated by exposing the substrate to excited species in a plasma. Pre-treating of the substrate can, for example, utilize a plasma source as shown in any of FIGS. 1-5. In one embodiment of the invention, the pre-treating can be carried out in a processing system as schematically shown in FIG. 5B, with about 500 Watts (W) to about 3,000 W, for example about 1,100 W of RF power between about 0.1 MHz and about 100 MHz, for example about 0.45 MHz, coupled to the inductive coil 195, and between about 0 W to about 2,000 W, for example 700 W, of RF power at between about 0.1 MHz and about 100 MHz, for example about 13.6 MHz, applied to the substrate holder 120. The pressure in the process chamber can be between about 0.3 mTorr to about 3,000 mTorr, for example about 0.5 mTorr. A pre-treatment gas, for example, H₂, N₂, NH₃, He, Ne, Ar, Kr, or Xe or a combination of two or more thereof with a gas flow rate between about 1 sccm and about 1000 sccm, for example about 2.5 sccm, can be utilized for forming excited species in a plasma for pre-treating the substrate. The substrate temperature can be between about −30° C. and about 500° C. In one embodiment of the invention, the substrate can be pre-treated for between about 5 seconds and about 300 seconds, for example, about 60 seconds.

At 804, the pre-treated substrate is exposed to a process gas containing a metal-carbonyl precursor gas, and at 806, a metal layer is formed on the pre-treated substrate by a chemical vapor deposition process. The chemical vapor deposition process can include, for example, TCVD, ALCVD, and/or PECVD. When the desired metal layer has been formed on the substrate, the process ends at 808.

The metal layer can be formed on the pre-treated substrate from a process gas containing metal-carbonyl precursor. A carrier gas, a dilution gas, and/or a purge gas can also be included as an option. The process gas flow rate can, for example, be between about 10 sccm and about 3,000 sccm. The metal-carbonyl flow rate can, for example, be between about 0.1 sccm and about 200 sccm. The carrier gas, dilution gas, and/or the purge gas can, for example, contain an inert gas such as He, Ne, Ar, Kr, or Xe or any combination thereof. Furthermore, the process gas can contain H₂ and/or N₂. In one embodiment of the invention, the carrier gas flow rate can be between about 1 sccm and about 100 sccm, for example about 20 sccm, the dilution gas flow rate can be between about 10 sccm and about 2,000 sccm, for example about 600 sccm, and the purge gas flow rate can be between about 10 sccm and about 2,000 sccm. The substrate temperature during formation of the metal layer can be between about 250° C. and about 600° C. Alternately, the substrate temperature can be between about 250° C. and about 600° C. The process pressure can, for example, be between about 10 mTorr and about 5 Torr.

Suitable process conditions that enable pre-treatment of a substrate and subsequent formation of a metal layer with desired thickness can be determined by direct experimentation and/or design of experiments (DOE). Adjustable process parameters can, for example, comprise substrate temperature, plasma power, chamber pressure, process gases, and relative gas flow rates.

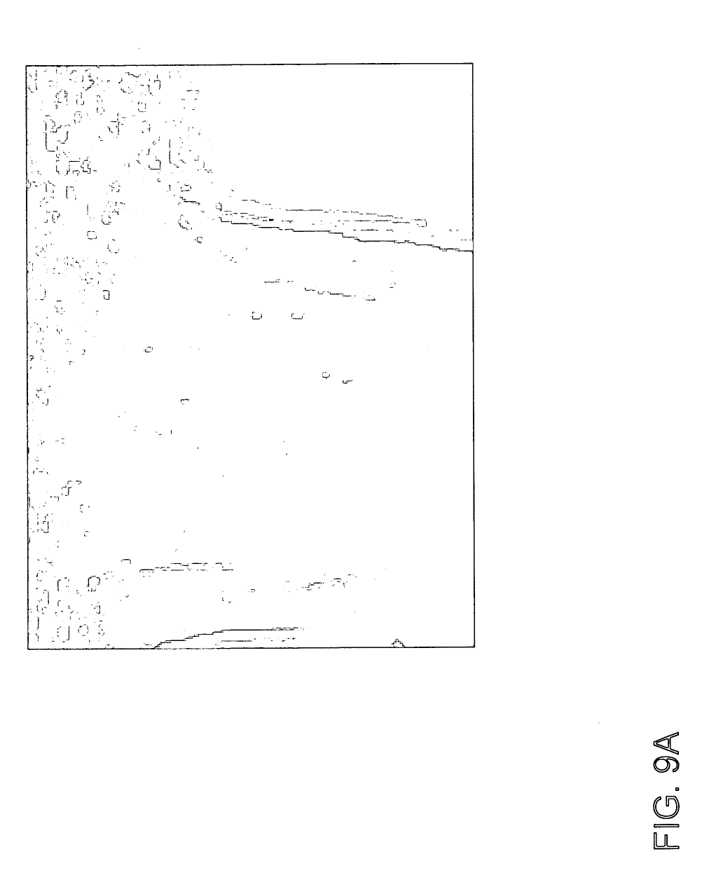

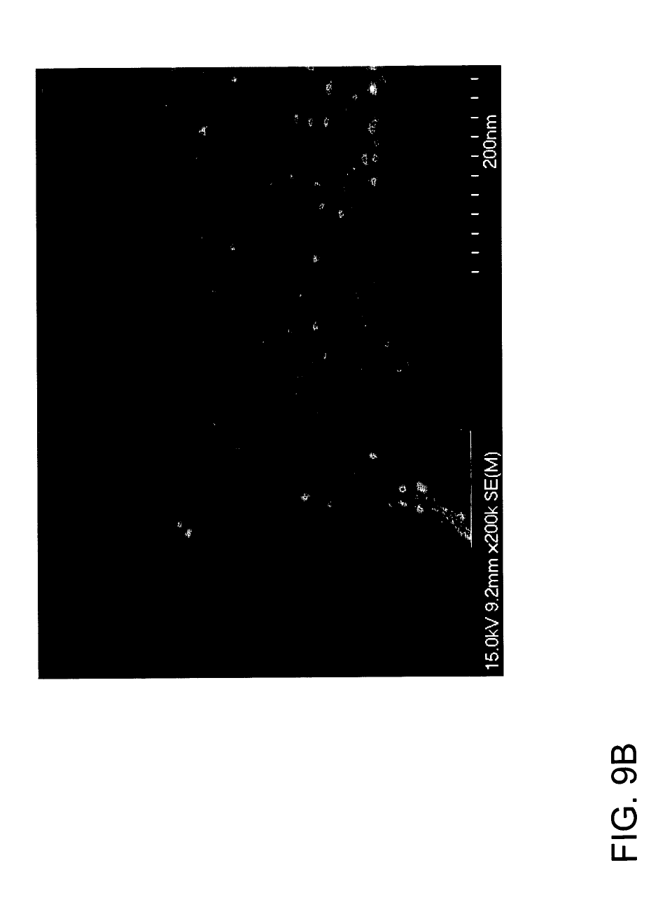

FIG. 9A shows a cross-sectional SEM picture of a W layer formed on a substrate containing a microstructure. The approximately 140 angstroms (Å) thick W layer was deposited on a substrate containing a microstructure in a thermal chemical vapor deposition process from a process gas containing a W(CO)₆ precursor, about 20 sccm of Ar carrier gas, and about 600 sccm of Ar dilution gas. The substrate holder temperature was abut 480° C. and the substrate temperature was about 410° C.

FIG. 9B shows a cross-sectional SEM picture of a W layer formed on a substrate containing a microstructure according to an embodiment of the invention. The substrate was pre-treated using a processing system schematically shown in FIG. 5B. The pre-treating included applying a power of about 1,100 W at about 0.45 MHz to an inductive coil, applying a bias of about 700 W at about 13.6 MHz to the substrate holder, maintaining a process chamber pressure of about 0.5 mTorr, Ar gas flow of about 2.5 sccm, and a pre-treating time of about 60 seconds. Following the pre-treating of the substrate, a W layer was formed onto the pre-treated substrate using the processing conditions as described above for FIG. 9A. A visual comparison of the SEM pictures in FIGS. 9A and 9B, shows that the W layer deposited on the pre-treated substrate in FIG. 9B is smoother and contains fewer nodules than the W layer deposited on the substrate in FIG. 9A that was not pre-treated.

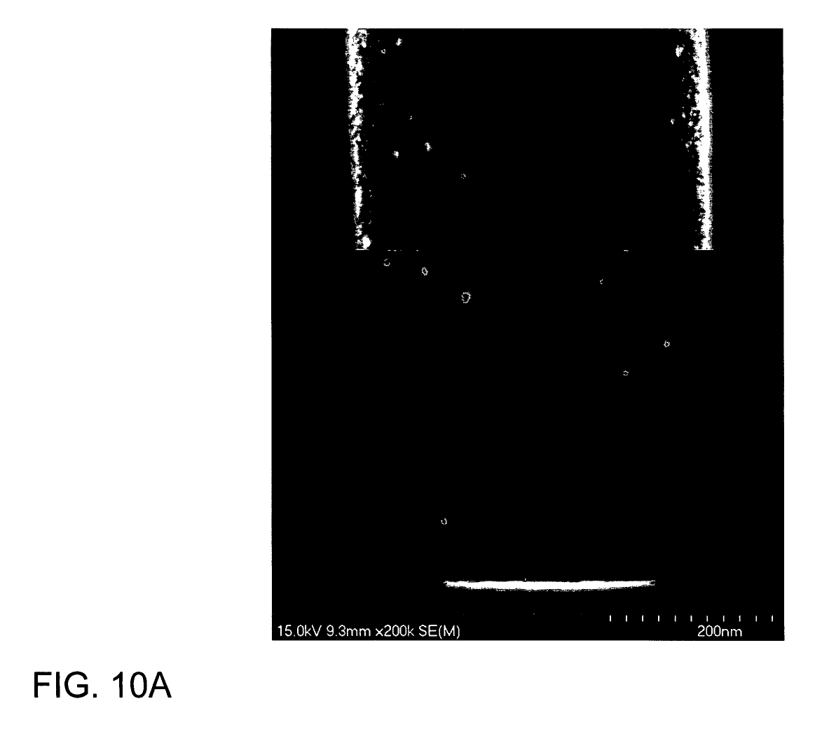

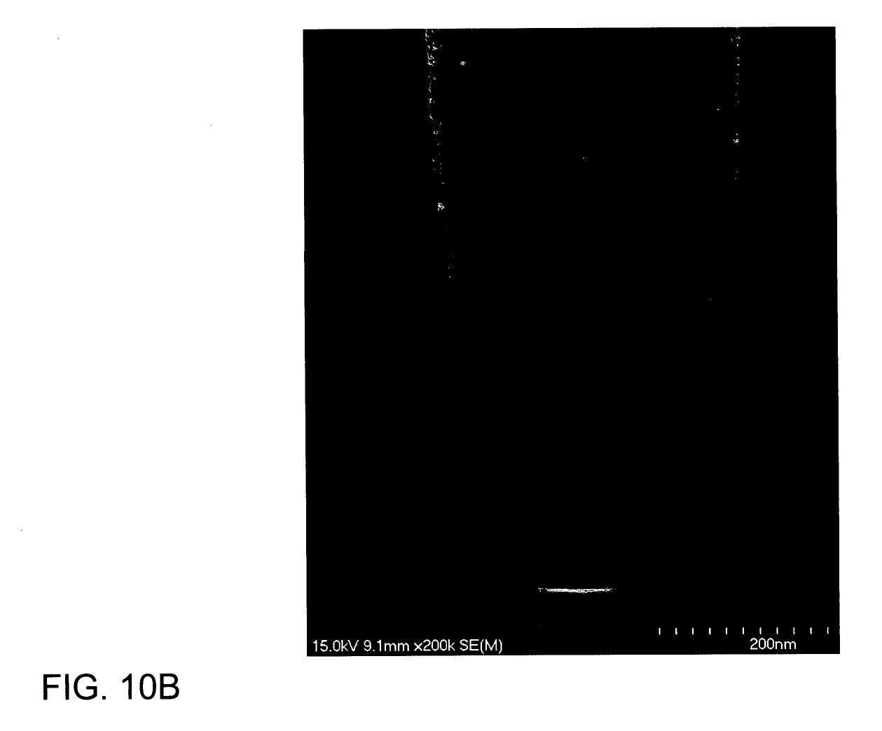

FIG. 10A shows a cross-sectional SEM picture of a W layer formed on a substrate containing a microstructure. The W layer in FIG. 10A was deposited using the same process conditions as used in FIG. 9A. FIG. 10B shows a cross-sectional SEM picture of a W layer formed on a microstructure according to an embodiment of the invention. The substrate was pre-treated and the W layer was deposited on the pre-treated substrate using the same process conditions as in FIG. 9B. A visual comparison of the SEM pictures in FIGS. 10A and 10B, shows that the W layer formed on the pre-treated substrate in FIG. 10B is smoother and contains fewer nodules than the W layer deposited on the substrate in FIG. 10A that was not pre-treated.

It should be understood that various modifications and variations of the present invention may be employed in practicing the invention. It is therefore to be understood that, within the scope of the appended claims, the invention may be practiced otherwise than as specifically described herein.

1. A method of forming a metal layer on a substrate, the method comprising:
pre-treating the substrate by exposing the substrate to excited species in a plasma;
exposing the pre-treated substrate to a process gas containing a metal-carbonyl precursor; and
forming a metal layer on the pre-treated substrate by a chemical vapor deposition process.

2. The method according to claim 1, wherein the substrate comprises a semiconductor substrate, a LCD substrate, or a glass substrate.

3. The method according to claim 1, wherein the pre-treating comprises:
creating a plasma from a pre-treatment gas including H₂, N₂, NH₃, He, Ne, Ar, Kr, or Xe or a combination of two or more thereof; and
exposing the substrate to excited species in the plasma.

4. The method according to claim 3, wherein the creating further comprises energizing an inductive coil and/or a substrate holder.

5. The processing system according to claim 4, wherein the energizing comprises applying RF power between about 500 W and about 3,000 W at a frequency between about 0.1 MHz and about 100 MHz to the inductive coil and/or applying RF power between about 0 W and about 2,000 W at a frequency between about 0.1 MHz and about 100 MHz to the substrate holder.

6. The method according to claim 3, wherein the creating further comprises flowing the pre-treatment gas at a gas flow rate between about 1 sccm and about 1,000 sccm.

7. The method according to claim 3, wherein the creating further comprises providing a pre-treatment gas pressure between about 0.3 mTorr and about 3,000 mTorr.

8. The method according to claim 1, wherein the pre-treating further comprises providing a substrate temperature between about −30° C. and about 500° C.

9. The method according to claim 1, wherein the pre-treating comprises exposing the substrate to excited species in a plasma for between about 5 seconds and about 300 seconds.

10. The method according to claim 1, wherein the process gas comprises W(CO)₆, Ni(CO)₄, Mo(CO)₆, CO₂(CO)₈, Rh₄(CO)₁₂, Re₂(CO)₁₀, Cr(CO)₆, or Ru₃(CO)₁₂ or a combination of two or more thereof.

11. The method according to claim 1, wherein the process gas comprises a metal-carbonyl precursor and H₂, N₂, He, Ne, Ar, Kr, or Xe, or a combination of two or more thereof.

12. The method according to claim 1, wherein the exposing includes flowing the process gas at a gas flow rate between about 10 sccm and about 3,000 sccm.

13. The method according to claim 1, wherein the exposing includes flowing the metal-carbonyl precursor at a gas flow rate between about 0.1 sccm and about 200 sccm.

14. The method according to claim 1, wherein the forming comprises forming a layer containing W, Ni, Mo, Co, Rh, Re, Cr, or Ru, or a combination of two or more thereof.

15. The method according to claim 1, wherein the forming further comprises heating the substrate to between about 250° C. and about 600° C.

16. The method according to claim 1, wherein the forming further comprises heating the substrate to about 400° C.

17. The method according to claim 1, wherein the forming further comprises providing a process gas pressure between about 10 mTorr and about 5 Torr.

18. The method according to claim 1, wherein the chemical vapor deposition process comprises thermal chemical vapor deposition, atomic layer chemical vapor deposition, or plasma-enhanced chemical vapor deposition or any combination thereof.

19. The method according to claim 1, wherein the pre-treating, exposing, and forming are carried out in at least one processing system.

20. A method of forming a tungsten layer on a substrate, the method comprising:
pre-treating the substrate by exposing the substrate to excited species in a plasma, wherein the plasma is formed from a pre-treatment gas containing H₂, N₂, NH₃, He, Ne, Ar, Kr, or Xe or a combination of two or more thereof;
exposing the pre-treated substrate to a process gas containing a W(CO)₆ precursor; and
forming a tungsten layer on the pre-treated substrate by a thermal chemical vapor deposition process.

21. A processing tool for forming a metal layer, comprising:
a transfer system configured for transferring a substrate within the processing tool;
at least one processing system configured for pre-treating a substrate by exposing the substrate to excited species in a plasma and exposing the pre-treated substrate to a process gas containing a metal-carbonyl precursor to form a metal layer on the pre-treated substrate in a chemical vapor deposition process; and
a controller configured to control the processing tool.

22. The processing tool according to claim 21, wherein the substrate comprises a semiconductor substrate, a LCD substrate, or a glass substrate.

23. The processing tool according to claim 21, wherein the at least one processing system contains a plasma created from a pre-treatment gas containing H₂, N₂, NH₃, He, Ne, Ar, Kr, or Xe or a combination of two or more thereof, the substrate being exposed to excited species in the plasma.

24. The processing tool according to claim 23, wherein the at least one processing system includes a plasma source configured to create the plasma.

25. The processing tool according to claim 24 wherein the plasma source includes an inductive coil and/or a substrate holder.

26. The processing tool according to claim 25, wherein the plasma source is configured for applying RF power between about 500 W and about 3,000 W at a frequency between about 0.1 MHz and about 100 MHz to the inductive coil and/or applying RF power between about 0 W and about 2,000 W at a frequency between about 0.1 MHz and about 100 MHz to the substrate holder.

27. The processing tool according to claim 23, wherein the at least one processing system comprises a gas delivery system configured to flow the pre-treatment gas at a gas flow rate between about 1 sccm and about 1,000 sccm.

28. The processing tool according to claim 23, wherein the at least one processing system provides a pre-treatment gas pressure between about 0.3 mTorr and about 3,000 mTorr.

29. The processing tool according to claim 21, wherein the at least one processing system provides a substrate pre-treating temperature between about −30° C. and about 500° C.

30. The processing tool according to claim 21, wherein the at least one processing system exposes the substrate to excited species in a plasma for between about 5 seconds and about 300 seconds.

31. The processing tool according to claim 21, wherein the process gas comprises W(CO)₆, Ni(CO)₄, Mo(CO)₆, CO₂(CO)₈, Rh₄(CO)₁₂, Re₂(CO)₁₀, Cr(CO)₆, or Ru₃(CO)₁₂ or a combination of two or more thereof.

32. The processing tool according to claim 21, wherein the process gas comprises a metal-carbonyl precursor and H₂, He, Ne, Ar, Kr, or Xe or a combination of two or more thereof.

33. The processing tool according to claim 21, wherein the at least one processing system comprises a gas delivery system which causes the process gas to flow at a gas flow rate between about 10 sccm and about 3,000 sccm.

34. The processing tool according to claim 21, wherein the at least one processing system comprises a gas delivery system which causes the metal-carbonyl precursor to flow at a gas flow rate between about 0.1 sccm and about 200 sccm.

35. The processing tool according to claim 21, wherein the at least one processing system forms the metal layer containing W, Ni, Mo, Co, Rh, Re, Cr, or Ru or a combination of two or more thereof.

36. The processing tool according to claim 21, wherein the at least one processing system heats the substrate to between about 250° C. and about 600° C. while forming the metal layer.

37. The processing tool according to claim 21, wherein the at least one processing system heats the substrate to about 400° C. while forming the metal layer.

38. The processing tool according to claim 21, wherein at least one processing system provides a process gas pressure between about 10 mTorr and about 5 Torr.

39. The processing tool according to claim 21, wherein the chemical vapor deposition process comprises thermal chemical vapor deposition, atomic layer chemical vapor deposition, or plasma-enhanced chemical vapor deposition or any combination thereof.

40. The processing tool according to claim 21, wherein the at least one processing system includes only one processing system.

41. The processing tool according to claim 21, wherein the at least one processing system includes at least two processing systems.

42. The processing tool according to claim 24, wherein the plasma source comprises a remote plasma source, an inductive coil, a plate electrode, an antenna, an ECR source, a Helicon wave source, or a surface wave source or any combination of two or more thereof.
